(19) United States
(12) Patent Application Publication
(10) Pub. No.: US 2026/0328634 A1
(43) Pub. Date: Oct. 22, 2026

(54) PRESSURE SENSOR

(71) Applicant: Murata Manufacturing Co., Ltd., Nagaokakyo-shi (JP)

(72) Inventor: Yoshihiro YOSHIDA, Nagaokakyo-shi (JP)

(21) Appl. No.: 19/696,785

(22) Filed: Jun. 3, 2026

Related U.S. Application Data
(63) Continuation of application No. PCT/JP2024/043747, filed on Dec. 11, 2024.

(30) Foreign Application Priority Data
Jan. 16, 2024 (JP) 2024-004713

(51) Int. Cl. G01L 9/00

(52) U.S. Cl. CPC G01L 9/0072; G01L 9/0052

(57) ABSTRACT

A pressure sensor including: a substrate; a detecting element adjacent an upper surface of the substrate; and a covering resin covering a part of the detecting element. The covering resin defines a covering recess where at least a part of the detecting element is exposed therethrough. The detecting element includes a detector, a groove portion recessed downward from an element upper surface and that surrounds the detector, and an internally recessed portion between the groove portion and the detector and that is recessed downward to a lesser depth than the groove portion. The internally recessed portion has a side surface extending downward from the element upper surface, and a bottom surface extending toward an outer side surface to connect the side surface of the internally recessed portion and the inner side surface of the groove portion.

### CROSS REFERENCE TO RELATED APPLICATIONS

The present application is a continuation of International application No. PCT/JP2024/043747, filed Dec. 11, 2024, which claims priority to Japanese Patent Application No. 2024-004713, filed Jan. 16, 2024, the entire contents of each of which are incorporated herein by reference.

### TECHNICAL FIELD

The present disclosure relates to a sensor that detects pressure.

### BACKGROUND ART

For example, a sensor described in Patent Document 1 is known as this type of sensor. The sensor described in Patent Document 1 includes a plate-shaped base portion, a semiconductor substrate disposed at an upper surface of the base portion, and a covering resin disposed at the upper surface of the base portion to cover a part of the semiconductor substrate. The semiconductor substrate has a recess that is recessed upward from the lower surface or a surface that is in contact with the base portion. The bottom portion of the recess forms a detector to which, for example, a resistor for measuring the flow rate is attached.

The semiconductor substrate includes a loop-shaped groove portion that is recessed downward from the upper surface of the semiconductor substrate and that surrounds the detector in a plan view. A covering resin is disposed at the upper surface of the base portion to cover the edge portion of the semiconductor substrate while allowing an exposed portion including the detector and the groove portion to be exposed therethrough in a plan view.

Patent Document 1: Japanese Unexamined Patent Application Publication No. 2017-227451

### SUMMARY OF THE DISCLOSURE

In the process of manufacturing a sensor, a covering resin is formed by pouring an uncured resin into a space between the base portion at which the semiconductor substrate is disposed, and a die disposed on the base portion. At this time, a part of the die comes into contact with the exposed portion of the semiconductor substrate, and thus reduces the likelihood of the resin reaching the exposed portion.

In contrast, to reduce damage caused when the exposed portion comes into contact with the die, a film may be disposed at an opposing surface of the die that faces the base portion. In this case, the film comes into contact with the exposed portion of the semiconductor substrate instead of the die. The manufacturing process involving use of the film is known as a film assisted molding process (FAM process).

To form a covering resin by the FAM process, depending on the conditions, such as inflow pressure of resin or pressure from the die on the base portion, the uncured resin may flow into a gap between the exposed portion and the film. In the sensor, the resin that has flowed into the gap reaches the groove portion earlier than it reaches the detector, and remains in the groove portion. The sensor described in Patent Document 1 thus reduces the likelihood of resin reaching the detector.

However, in the sensor described in Patent Document 1, a substance with low fluidity in the resin falls into the groove portion, whereas a substance with high fluidity in the resin trickles along the surface of the film, and may cross over the groove portion. Thus, the substance with high fluidity may reach the detector. When the substance with high fluidity adheres to the detector, the substance hinders the measuring operation of the detector, and lowers the characteristics of the sensor. More specifically, the sensor described in Patent Document 1 has room for improvement in terms of reducing the likelihood of uncured resin reaching the detector.

The present disclosure aims to address the above issue, and to provide a pressure sensor capable of reducing the likelihood of uncured resin reaching the detector.

A pressure sensor according to the present disclosure includes: a substrate having a first surface and a second surface opposing each other in a thickness direction thereof; a detecting element adjacent the first surface of the substrate and configured to detect a pressure; and a covering resin adjacent the first surface of the substrate and covering a part of the detecting element, wherein the covering resin defines a covering recess that is recessed toward the first surface of the substrate such that at least a part of an element surface of the detecting element is exposed therethrough, wherein the detecting element includes: a detector disposed at a portion of the element surface exposed through the covering recess, a groove portion that is recessed downward from the element surface and that surrounds the detector in a plan view of the pressure sensor, and an internally recessed portion between the groove portion and the detector in the plan view and continuous with the groove portion, the internally recessed portion being recessed toward the first surface of the substrate to a lesser depth than the groove portion, wherein the groove portion has a first side surface and a second side surface, the second side surface being closer to the detector than the first side surface in the plan view, and the second side surface faces the first side surface, and wherein the internally recessed portion has a third side surface extending toward the first surface of the substrate from the element surface, and a bottom surface extending toward the first side surface from an edge portion of the third side surface of the internally recessed portion.

According to the present disclosure, a pressure sensor capable of reducing the likelihood of uncured resin reaching a detector can be provided.

### BRIEF DESCRIPTION OF THE DRAWINGS

FIG. 1 is a plan view of a pressure sensor according to a first embodiment of the present disclosure.

FIG. 2 is a cross-sectional view taken along line A1-A1 in FIG. 1.

FIG. 3 is a plan view of a detecting element included in the pressure sensor in FIG. 1.

FIG. 4 is an enlarged cross-sectional view of a Z1 area in FIG. 2.

FIG. 5 is an enlarged cross-sectional view of a Z2 area in FIG. 4.

FIG. 6 is a cross-sectional view describing an example of a process of manufacturing the pressure sensor in FIG. 1.

FIG. 7 is an enlarged cross-sectional view of a Z3 area in FIG. 6.

FIG. 8 is an enlarged cross-sectional view of a pressure sensor according to a second embodiment of the present disclosure, corresponding to the view in FIG. 4.

FIG. 9 is an enlarged cross-sectional view of a pressure sensor according to a third embodiment of the present disclosure, corresponding to the view in FIG. 4.

FIG. 10 is a cross-sectional view of a pressure sensor according to a fourth embodiment of the present disclosure.

FIG. 11 is a plan view of an element upper surface of a pressure sensor according to a fourth embodiment of the present disclosure.

### DESCRIPTION OF THE PREFERRED EMBODIMENTS

Hereafter, embodiments of the present disclosure are described with reference to attached drawings. In the description below, terms indicating specific directions or positions (including, for example, “upper”, “lower”, “right”, and “left”) may be used as needed. Such terms are used solely for the purpose of facilitating understanding of the present disclosure with reference to the drawings and are not intended to limit the technical scope of the present disclosure. Further, the following description is merely illustrative in nature and is not intended to limit the present disclosure, its applications, or its uses. Moreover, the drawings are schematic, and the dimensional ratios and other characteristics do not necessarily correspond to actual ones.

Herein, the term “electrically connected” includes any of a state in which current is capable of flowing between multiple components, a state in which the multiple components are capacitively coupled, and a state in which the multiple components are electromagnetically coupled.

### First Embodiment

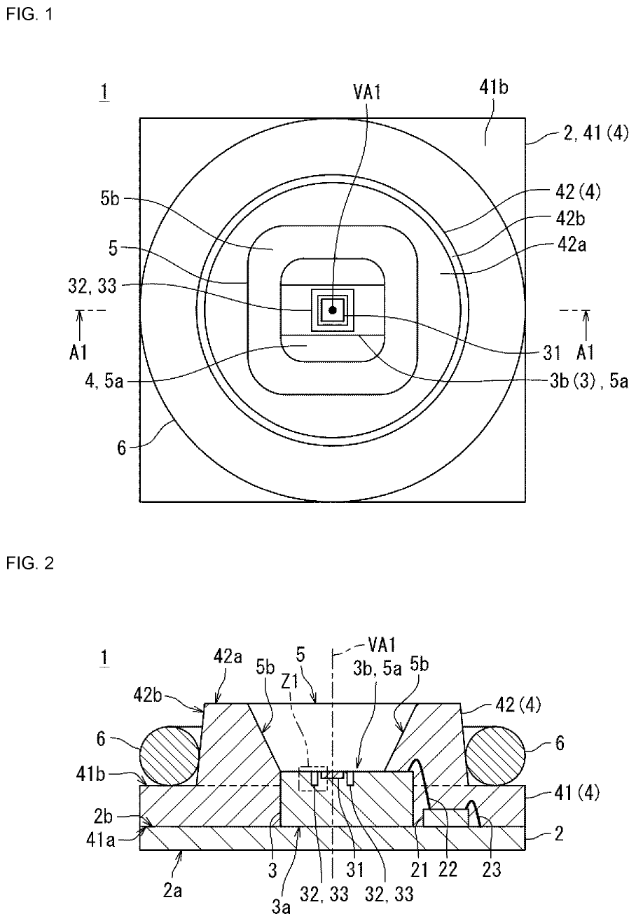

With reference to FIG. 1 and FIG. 2, a pressure sensor according to a first embodiment of the present disclosure is described. FIG. 1 is a plan view of a pressure sensor according to the first embodiment of the present disclosure. FIG. 2 is a cross-sectional view taken along line A1-A1 in FIG. 1.

As illustrated in FIG. 1 and FIG. 2, a pressure sensor 1 according to the first embodiment includes a substrate 2, a detecting element 3 disposed on the substrate 2, and a covering resin 4 disposed on the substrate 2 to cover the detecting element 3. For example, the pressure sensor 1 is capable of measuring various pressures, such as absolute pressure, gauge pressure, differential pressure, and airflow pressure.

As illustrated in FIG. 2, the substrate 2 has a lower surface 2a and an upper surface 2b opposite the lower surface 2a. For example, the substrate 2 is a wiring board such as a resin substrate, a ceramic substrate, or a lead frame. In the present embodiment, the substrate 2 is a printed circuit board. In the example illustrated in FIG. 1, in a plan view when viewed in the vertical direction, the substrate 2 is a square having sides extending in two directions intersecting with the vertical direction and intersecting with each other.

As illustrated in FIG. 2, the detecting element 3 and a circuit element 21 are disposed at the upper surface 2b of the substrate 2. The detecting element 3 is a pressure sensor element that detects pressure. For example, the detecting element 3 is a piezoresistive or capacitive pressure sensor element, and is a micro-electromechanical systems (MEMS) element. In the present embodiment, the detecting element 3 is a rectangular prism, and has an element lower surface 3a that faces the upper surface 2b of the substrate 2, and an element upper surface 3b opposite the element lower surface 3a. The detecting element 3 includes a detector 31 that is disposed at the element upper surface 3b, and to which pressure is applied. For example, the detector 31 is a membrane or a diaphragm that receives pressure.

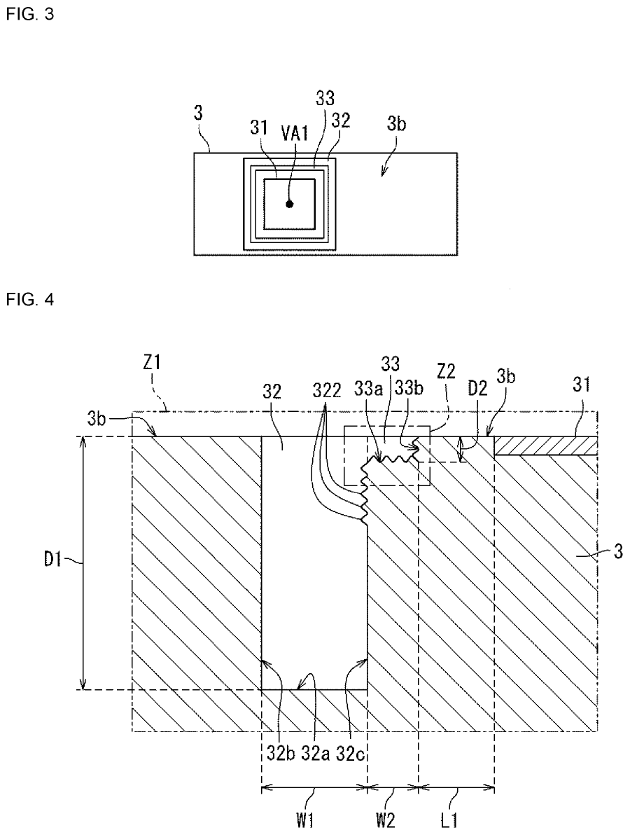

FIG. 3 is a plan view of a detecting element included in the pressure sensor in FIG. 1. As illustrated in FIG. 3, the detector 31 is located at the element upper surface 3b at a distance from the edge portion of the element upper surface 3b. In a plan view, the detector 31 is rotationally symmetric about a virtual center axis VA1 extending in the vertical direction. In the present embodiment, the detector 31 is rectangular in a plan view.

As illustrated in FIG. 2 and FIG. 3, the detecting element 3 includes a groove portion 32 and an internally recessed portion 33 recessed downward in the vertical direction from the element upper surface 3b. The groove portion 32 and the internally recessed portion 33 surround the detector 31 in a plan view. In the present embodiment, the groove portion 32 and the internally recessed portion 33 are continuous rectangles in a plan view. The internally recessed portion 33 is disposed between the detector 31 and the groove portion 32 to be continuous with the groove portion 32. More specifically, the direction in which the groove portion 32 extends matches the direction in which the internally recessed portion 33 extends. The direction in which the groove portion 32 and the internally recessed portion 33 extend includes directions along the four sides of the rectangles in the present embodiment. The detailed structures of the groove portion 32 and the internally recessed portion 33 are described later.

In the description below, a direction intersecting with both the vertical direction and a direction in which the groove portion 32 extends is also simply referred to as “a cross direction”. In the cross direction, a direction toward the detector 31 is also referred to as “inward”, and a direction away from the detector 31 is also referred to as “outward”. A cross section (refer to FIG. 4) intersecting with the direction in which the groove portion 32 or the internally recessed portion 33 extends is also simply referred to as “a cross section of the groove portion 32 or the internally recessed portion 33”.

The circuit element 21 is an element that includes, for example, an application-specific integrated circuit (ASIC). In the present embodiment, the circuit element 21 includes, for example, a converter that converts a voltage signal output from the detecting element 3 to a digital signal, a filter that filters the digital signal from the converter, a temperature sensor that detects temperature, a processor that corrects the filtered digital signal on the basis of the temperature detected by the temperature sensor, and a memory that stores, for example, a correction factor used to correct the digital signal using the detected temperature.

In the present embodiment, as illustrated in FIG. 2, the detecting element 3 and the circuit element 21 are disposed at the upper surface 2b of the substrate 2 and arranged side by side. For example, each of the detecting element 3 and the circuit element 21 is joined to the substrate 2 using a binding material such as a die attach film or a die bonding material.

In the present embodiment, the detecting element 3 and the circuit element 21 are connected to each other with a bonding wire 22. The circuit element 21 and the substrate 2 are connected to each other with a bonding wire 23. Thus, a circuit disposed on the substrate 2, the detecting element 3, and the circuit element 21 are electrically connected.

The detecting element 3 and the circuit element 21 may be electrically connected with a circuit on the substrate 2. For example, each of the detecting element 3 and the circuit element 21 may be connected to the circuit on the substrate 2 through a bonding wire or a bump. The detecting element 3 and the circuit element 21 may overlap on the substrate 2 in the vertical direction.

The covering resin 4 is disposed at the upper surface 2b of the substrate 2, and covers a part of the detecting element 3, the circuit element 21, and the bonding wires 22 and 23. The covering resin 4 includes a body 41 disposed at the upper surface 2b of the substrate 2, and a covering protrusion 42 that protrudes upward from the body 41 in the vertical direction. The body 41 has a lower surface 41a that faces the substrate 2, and an upper surface 41b opposite the lower surface 41a. The covering protrusion 42 protrudes from the upper surface 41b of the body 41. The body 41 and the covering protrusion 42 are integrally formed as described later. For example, the covering resin 4 is formed from epoxy resin, unsaturated polyester resin, or phenolic resin. FIG. 2 illustrates a boundary between the body 41 and the covering protrusion 42 with broken lines.

For example, each of the body 41 and the covering protrusion 42 is circular, elliptical, or polygonal in a plan view. As illustrated in FIG. 1 and FIG. 2, the body 41 is a rectangular prism in the present embodiment, and disposed throughout the upper surface 2b of the substrate 2.

The covering protrusion 42 has a truncated cone shape that tapers upward in the vertical direction. The covering protrusion 42 has an upper surface 42a, or a top surface, and an outer wall surface 42b that connects the upper surface 42a and the upper surface 41b of the body 41. The upper surface 42a of the covering protrusion 42 forms a part of the upper surface of the covering resin 4.

An O-ring 6 may be disposed at the upper surface 41b of the body 41 to surround the covering protrusion 42 in a plan view. For example, the O-ring 6 is formed from an elastic material such as rubber or silicone. The O-ring 6 may be disposed around the covering protrusion 42 while being stretched, and in contact with the outer wall surface 42b of the covering protrusion 42. In this case, when the pressure sensor 1 is attached to an electronic device, the O-ring 6 may be squeezed between a housing of the electronic component and the pressure sensor 1 to be elastically deformed, and may thus block inflow of water between these.

The covering resin 4 includes a covering recess 5 that is recessed downward in the vertical direction from the upper surface 42a of the covering protrusion 42, and that allows a part of the detecting element 3 to be exposed therethrough. In the example illustrated in FIG. 1, the covering recess 5 allows the detector 31, the groove portion 32, and the internally recessed portion 33 of the detecting element 3 to be exposed therethrough. More specifically, the covering resin 4 covers the detecting element 3 at a portion excluding the covering recess 5.

As illustrated in FIG. 2, in the present embodiment, the covering recess 5 has a tapered shape in which an open surface decreases as it extends further from the upper surface 42a of the covering protrusion 42 in the vertical direction. In the present embodiment, the covering recess 5 is rotationally symmetric about a virtual center axis VA1 extending in the vertical direction. As illustrated in FIG. 1, the open surface of the covering recess 5 has a substantially rectangular shape with rounded corners in a plan view.

The covering recess 5 has a bottom surface 5a from which the detecting element 3 is exposed, and an inner wall surface 5b that connects the bottom surface 5a and the upper surface 42a of the covering protrusion 42.

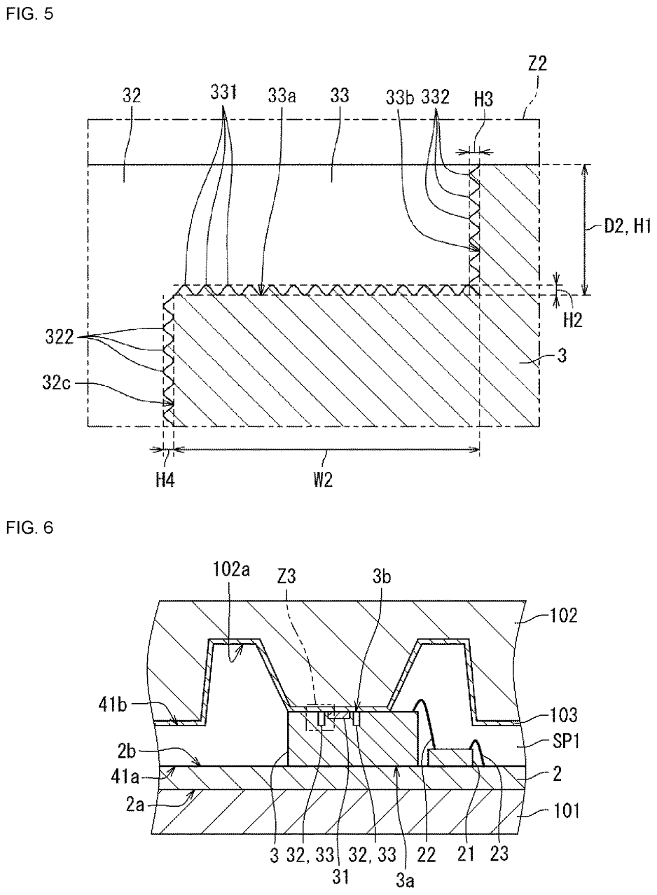

With reference to FIG. 4 and FIG. 5, the structures of the groove portion 32 and the internally recessed portion 33 are described. FIG. 4 is an enlarged cross-sectional view of a Z1 area in FIG. 2. FIG. 5 is an enlarged cross-sectional view of a Z2 area in FIG. 4. FIG. 4 illustrates a boundary between the groove portion 32 and the internally recessed portion 33 with a broken line.

The groove portion 32 and the internally recessed portion 33 are rotationally symmetric about the virtual center axis VA1. Thus, the groove portion 32 and the internally recessed portion 33 have the same cross section as that in FIG. 4 throughout the entire periphery.

As illustrated in FIG. 4, the groove portion 32 has a bottom surface 32a that intersects with the vertical direction, and two side surfaces (an outer side surface 32b and an inner side surface 32c) extending in the vertical direction. In the cross section of the groove portion 32, a width W1 of the bottom surface 32a in the cross direction is, for example, 10μm.

Of the two side surfaces, the outer side surface 32b is a side surface located closer to the outside, and connects the bottom surface 32a and an area located closer to the outside than the groove portion 32 of the element upper surface 3b. The inner side surface 32c is a side surface located closer to the inside than the outer side surface 32b in a plan view, and faces the outer side surface 32b in the cross direction. In the present embodiment, a depth D1 of the groove portion 32 from the element upper surface 3b is 100 μm.

The internally recessed portion 33 is located closer to the inside than the groove portion 32 to be continuous with the groove portion 32. The internally recessed portion 33 is recessed downward from the element upper surface 3b to a lesser depth than the groove portion 32. In the present embodiment, a depth D2 of the internally recessed portion 33 from the element upper surface 3b is 4 μm.

The internally recessed portion 33 has a bottom surface 33a intersecting with the vertical direction, and a side surface 33b that connects the bottom surface 33a and the element upper surface 3b in the vertical direction.

With reference to FIG. 5, the structures of the bottom surface 33a and the side surface 33b of the internally recessed portion are described. FIG. 5 is an enlarged cross-sectional view of a Z2 area in FIG. 4.

The bottom surface 33a of the internally recessed portion connects the inner side surface 32c of the groove portion and the side surface 33b of the internally recessed portion. More specifically, the inner side surface 32c of the groove portion connects the bottom surface 32a of the groove portion and the bottom surface 33a of the internally recessed portion. More specifically, the bottom surface 33a extends from the lower edge portion of the side surface 33b of the internally recessed portion toward the outer side surface 32b of the groove portion. In the example illustrated in FIG. 5, the bottom surface 33a of the internally recessed portion is orthogonal to the vertical direction.

In the cross section of the internally recessed portion 33, the bottom surface 33a has a width W2 in the cross direction. For example, the width W2 of the bottom surface 33a is a dimension of the bottom surface 33a between the lower edge portion of the side surface 33b of the internally recessed portion and an upper edge portion of the inner side surface 32c of the groove portion. As illustrated in FIG. 4, the width W2 of the bottom surface 33a is smaller than the distance L1 between the detector 31 and the upper edge portion of the side surface 33b of the internally recessed portion on the element upper surface 3b. In the present embodiment, the width W2 of the bottom surface 33a is 5 μm, which is smaller than the width W1 of the bottom surface 32a of the groove portion.

As illustrated in FIG. 5, in the present embodiment, the side surface 33b of the internally recessed portion extends downward from the element upper surface 3b, and reaches the inner edge portion of the bottom surface 33a. A height H1 of the side surface 33b in the vertical direction is smaller than the width W2 of the bottom surface 33a of the internally recessed portion in the cross direction. More specifically, the height H1 of the side surface 33b is smaller than a dimension of the bottom surface 33a of the internally recessed portion between the lower edge portion of the side surface 33b of the internally recessed portion and the upper edge portion of the inner side surface 32c of the groove portion. In the present embodiment, the bottom surface 33a is orthogonal to the vertical direction, and the height H1 of the side surface 33b matches the depth D2 of the internally recessed portion 33. More specifically, the height H1 of the side surface 33b is 4 μm.

The internally recessed portion 33 includes multiple protrusions 331 disposed on the bottom surface 33a and multiple projections 332 disposed on the side surface 33b.

On the bottom surface 33a, the multiple protrusions 331 are arranged in the cross direction. In the present embodiment, in a plan view, each protrusion 331 extends linearly in the direction in which the internally recessed portion 33 extends. In a plan view, the multiple protrusions 331 are arranged in a direction from the inner side surface 32c of the groove portion to the side surface 33b of the internally recessed portion.

In the present embodiment, the multiple protrusions 331 are disposed throughout the entire bottom surface 33a of the internally recessed portion in the cross direction. More specifically, the bottom surface 33a of the internally recessed portion is an uneven surface, with the multiple protrusions 331 and recesses between the multiple protrusions 331 alternating in the cross direction.

Each protrusion 331 has a height H2 from the bottom surface 33a of the internally recessed portion to the top of the protrusion 331. The height H2 is smaller than the depth D2 of the internally recessed portion 33. Thus, the top of each protrusion 331 is located below the open surface of the internally recessed portion 33. The height H2 may be the same or different between the protrusions 331. In the present embodiment, the protrusions 331 have the same height H2 of 1 μm.

On the side surface 33b, the multiple projections 332 are arranged in the vertical direction. In the present embodiment, each projection 332 extends linearly in the direction in which the internally recessed portion 33 extends. The multiple projections 332 are disposed throughout the entire side surface 33b of the internally recessed portion in the vertical direction. More specifically, the side surface 33b of the internally recessed portion is an uneven surface, with the multiple projections 332 and recesses between the multiple projections 332 alternating in the cross direction.

Each projection 332 has a height H3 from the side surface 33b of the internally recessed portion to the top of the projection 332. The height H3 may be the same or different between the projections 332. For example, the projections 332 have the same height H3 less than or equal to 1 μm.

As illustrated in FIG. 4, the groove portion 32 according to the present embodiment includes multiple projections 322 that are disposed on the inner side surface 32c and arranged downward from the upper edge portion of the inner side surface 32c, and that protrude from the inner side surface 32c. The multiple projections 322 may be disposed throughout the entire inner side surface 32c of the groove portion in the vertical direction, or disposed at a part of the inner side surface 32c in the vertical direction. In the example illustrated in FIG. 4, the multiple projections 322 are disposed simply in an upper area of the inner side surface 32c. The upper area includes the upper edge portion of the inner side surface 32c.

As illustrated in FIG. 5, each projection 322 has a height H4 from the inner side surface 32c of the groove portion to the top of the projection 322. The height H4 may be the same or different between the projections 322. For example, the projections 322 have the same height H4 less than or equal to 1 μm.

### Method for Forming Covering Resin

With reference to FIG. 6, a FAM process, which is an example of a method for forming the covering resin 4 in the pressure sensor 1, is described. FIG. 6 is a cross-sectional view of an example of a process for manufacturing the pressure sensor illustrated in FIG. 1.

In this process, the covering resin 4 is formed using two dies, or a lower die 101 and an upper die 102. In the process of forming the covering resin 4, a collective substrate including a large number of substrates 2 arranged in a planar direction is disposed on the lower die 101. FIG. 6 illustrates a portion of the collective substrate corresponding to one pressure sensor 1. Components including the detecting element 3, the circuit element 21, and the bonding wires 22 and 23 are installed on the substrate 2 on the lower die 101.

The upper die 102 has a lower surface 102a that faces the lower die 101 in the vertical direction. The lower surface 102a has a shape corresponding to the shape of the covering resin 4.

On the lower surface 102a, a film 103 that reduces adhesion of resin to the upper die 102 or damage of the detecting element 3 is disposed. For example, the film 103 is a release film containing Teflon (registered trademark).

The film 103 is heated by the upper die 102, and sucked to the lower surface 102a through a suction hole (not illustrated) open in the lower surface 102a of the upper die 102. After being heated, the film 103 becomes more flexible than before being heated, and is thus formed, by the suction, into a shape following the lower surface 102a.

The upper die 102 is fixed to the lower die 101 to hold the substrate 2 between itself and the lower die 101. At this time, the film 103 comes into contact with an area of the element upper surface 3b exposed through the covering recess 5. More specifically, the film 103 is in contact with the detector 31, the groove portion 32, and the internally recessed portion 33.

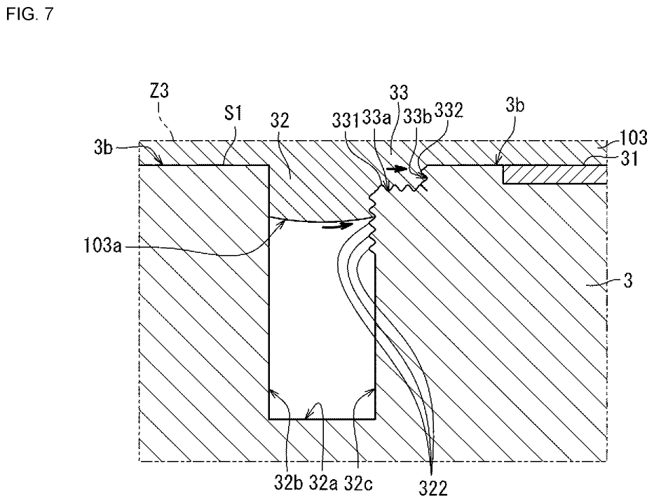

FIG. 7 is an enlarged cross-sectional view of a Z3 area in FIG. 6. As illustrated in FIG. 7, the film 103 having flexibility is pressed downward by the upper die 102 (refer to FIG. 6), and inserted into a part of the groove portion 32 and the internally recessed portion 33. At this time, the film 103 enters the recesses between the multiple projections 322 in the groove portion 32, and the recesses between the multiple protrusions 331 and the recesses between the multiple projections 332 of the internally recessed portion 33. Thus, the adhesion of the film 103 to the inner side surface 32c of the groove portion and the bottom surface 33a and the side surface 33b of the internally recessed portion improves. In other words, the adhesion of the film 103 to the detecting element 3 improves.

Each projection 322 of the groove portion 32 and each projection 332 of the internally recessed portion 33 reduce upward movement of the film 103 that has entered the recesses immediately below the projections. Thus, even when a force of pulling the film 103 upward is unintentionally exerted on the film 103, adhesion between the film 103 and the detecting element 3 can be more reliably maintained.

Resin to form the covering resin 4 is poured into a space SP1 (refer to FIG. 6) between the substrate 2 and the film 103 while being uncured. At this time, depending on the conditions such as contact pressure exerted on the detecting element 3 from the film 103, or inflow pressure of resin flowing into the space SP1, resin may access an interface S1 between the film 103 and the detecting element 3. The resin flows inward along the interface S1.

In the example illustrated in FIG. 7, resin flows rightward along the interface S1. Resin that has flowed along the interface S1 reaches the groove portion 32 before reaching the detector 31. In the groove portion 32, a substance in the resin with low fluidity (hereafter, also referred to as “a low-fluidity substance”) moves away from a surface 103a of the film 103, and falls into the groove portion 32. This structure thus reduces the likelihood of a low-fluidity substance reaching the detector 31. A substance in the resin with high fluidity (hereafter, also referred to as “a high-fluidity substance”) trickles along the surface 103a of the film with surface tension, and further moves inward toward the detector 31.

The inner side surface 32c of the groove portion and the side surface 33b of the internally recessed portion function as barriers to the high-fluidity substance moving inward. The high-fluidity substance that trickles along the surface 103a of the film first comes into contact with the inner side surface 32c of the groove portion, as indicated by an arrow in FIG. 7. At this time, the inward-directed force of the high-fluidity substance (rightward force in FIG. 7) is reduced.

The inner side surface 32c of the groove portion and the bottom surface 33a of the internally recessed portion firmly adhere to the film 103 with the presence of the projections 322 and the protrusions 331. This structure reduces the likelihood of a high-fluidity substance accessing the interface S1 or moving inward along the interface S1.

Unlike an existing sensor (such as a sensor described in Patent Document 1), a high-fluidity substance comes into contact with the side surface 33b of the internally recessed portion as indicated by arrow in FIG. 7. Thus, an inward-directed force of a high-fluidity substance (rightward force in FIG. 7) is further reduced.

As in the case of the inner side surface 32c of the groove portion and the bottom surface 33a of the internally recessed portion, the side surface 33b of the internally recessed portion also firmly adheres to the film 103 with the presence of the projections 332. This structure can further reduce the likelihood of a high-fluidity substance moving inward along the interface S1. Thus, as compared to an existing sensor, the pressure sensor 1 can reduce the likelihood that resin containing a high-fluidity substance reaches the detector while the covering resin 4 is formed.

In the pressure sensor 1 according to the first embodiment, the internally recessed portion 33 recessed downward to a lesser depth than the groove portion 32 is located between the groove portion 32 and the detector 31 to be continuous with the groove portion 32. In this structure, while the covering resin 4 is formed, a high-fluidity substance that moves inward while trickling along the surface 103a of the film comes into contact with the side surface 33b of the internally recessed portion in addition to the inner side surface 32c of the groove portion. This structure can thus reduce inward movement of a high-fluidity substance.

As compared to a structure not including the internally recessed portion 33, a structure including the internally recessed portion 33 that is continuous with the groove portion 32 in the cross direction allows the film 103 having flexibility to enter the groove portion 32 to a deeper position. This structure improves adhesion between the film 103 and the detecting element 3. This structure can thus reduce the likelihood of a high-fluidity substance accessing the interface S1 between the film 103 and the detecting element 3 or reduce the likelihood of a high-fluidity substance moving inward along the interface S1.

This structure can thus reduce the likelihood of uncured resin reaching the detector 31.

In the pressure sensor 1 according to the first embodiment, the internally recessed portion 33 includes multiple projections 332 disposed on the side surface 33b and arranged in the vertical direction. This structure allows the film 103 to enter the recesses between the projections 332 in the process of forming the covering resin 4. Thus, as compared to the structure not including the projections 332, adhesion between the film 103 and the side surface 33b of the internally recessed portion improves.

Each projection 332 reduces upward movement of the film 103 located in the recesses immediately below the projection 332. Thus, even when a force of pulling the film 103 upward is unintentionally exerted on the film 103, adhesion between the film 103 and the side surface 33b of the internally recessed portion can be more reliably maintained.

The presence of the projections 332 increases the length of the interface S1 from the inner side surface 32c of the groove portion to the detector 31 in the cross section of the groove portion 32 and the internally recessed portion 33. This structure reduces the likelihood of uncured resin reaching the detector 31. This structure can thus further reduce the likelihood of uncured resin reaching the detector 31.

In the pressure sensor 1 according to the first embodiment, the height H1 of the side surface 33b of the internally recessed portion is smaller than the width W2 of the bottom surface 33a of the internally recessed portion in the cross direction. As compared to a structure in which the height H1 is greater than the width W2, in this structure, the film 103 is more likely to come into contact with the bottom surface 33a of the internally recessed portion in the vertical direction. This structure can thus improve adhesion between the film 103 and the bottom surface 33a of the internally recessed portion, and can further reduce the likelihood of uncured resin reaching the detector 31.

In the pressure sensor 1 according to the first embodiment, the width W2 of the bottom surface 33a of the internally recessed portion in the cross direction is smaller than the distance L1 between the side surface 33b of the internally recessed portion and the detector 31 on the element upper surface 3b. As compared to a structure in which the width W2 is greater than the distance L1, this structure increases the distance between the internally recessed portion 33 and the detector 31 on the element upper surface 3b, and thus can further reduce the likelihood of uncured resin reaching the detector 31.

In the pressure sensor 1 according to the first embodiment, the internally recessed portion 33 includes the multiple protrusions 331 disposed on the bottom surface 33a and arranged in the cross direction. In this structure, in the process of forming the covering resin 4, the film 103 enters the recesses between the protrusions 331. As compared to the structure not including the protrusions 331, this structure improves adhesion between the film 103 and the bottom surface 33a of the internally recessed portion. This structure can thus further reduce the likelihood of uncured resin reaching the detector 31.

### Second Embodiment

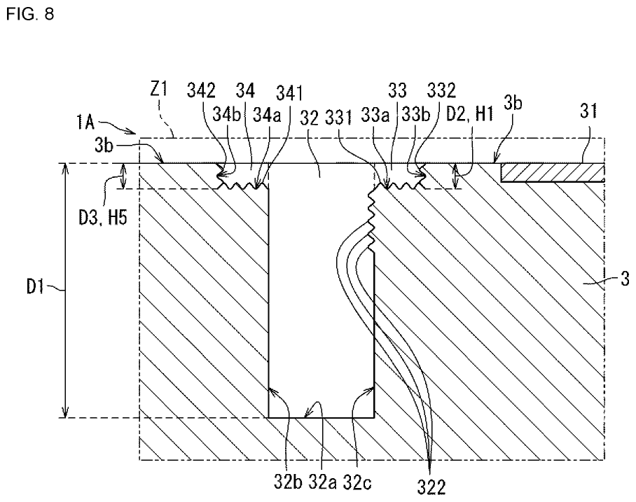

With reference to FIG. 8, a pressure sensor according to a second embodiment of the present disclosure is described. FIG. 8 is an enlarged cross-sectional view of a pressure sensor according to a second embodiment of the present disclosure, corresponding to the view in FIG. 4.

A pressure sensor 1A according to the second embodiment differs from the pressure sensor 1 according to the first embodiment in that the detecting element 3 includes an externally recessed portion 34. In the description of the second embodiment below, the same components as those in the pressure sensor 1 are denoted with the same reference signs, and not described.

As illustrated in FIG. 8, in the pressure sensor 1A, the detecting element 3 further includes an externally recessed portion 34 recessed downward to a lesser depth than the groove portion 32. FIG. 8 illustrates boundaries between the groove portion 32 and the internally recessed portion 33 and between the groove portion 32 and the externally recessed portion 34 with broken lines. In a plan view, the externally recessed portion 34 is located closer to the outside than the groove portion 32 in the cross direction to be continuous with the groove portion 32. More specifically, the externally recessed portion 34 is located to be continuous with the outer side surface 32b of the groove portion in a plan view. More specifically, the externally recessed portion 34 is located to be continuous with the groove portion 32 on the side opposite to, in the cross direction, the side on which the internally recessed portion 33 is located.

In the present embodiment, the groove portion 32, the internally recessed portion 33, and the externally recessed portion 34 are rotationally symmetric about the virtual center axis VA1 (refer to FIG. 3). Thus, the groove portion 32, the internally recessed portion 33, and the externally recessed portion 34 have the same cross section as the cross section illustrated in FIG. 8 throughout the entire periphery. The direction in which the externally recessed portion 34 extends matches the direction in which each of the groove portion 32 and the internally recessed portion 33 extends.

A depth D3 of the externally recessed portion 34 from the element upper surface 3b is smaller than the depth D1 of the groove portion 32. The depth D3 of the externally recessed portion 34 may be the same as the depth D2 of the internally recessed portion 33 or different from the depth D2. In the present embodiment, the depth D3 of the externally recessed portion 34 is the same as the depth D2 of the internally recessed portion 33 of 4 μm.

The externally recessed portion 34 has a bottom surface 34a intersecting with the vertical direction, and a side surface 34b that extends in the vertical direction and that connects the bottom surface 34a and the element upper surface 3b. The side surface 34b extends downward from an outer area of the externally recessed portion 34 of the element upper surface 3b. The bottom surface 34a connects the side surface 34b and the outer side surface 32b of the groove portion in the cross direction. In the example illustrated in FIG. 8, the bottom surface 34a is orthogonal to the vertical direction. Thus, a height H5 of the side surface 34b in the vertical direction is the same as the depth D3 of the externally recessed portion 34 of 4 μm.

As in the internally recessed portion 33, the externally recessed portion 34 includes multiple protrusions 341 disposed on the bottom surface 34a, and multiple projections 342 disposed on the side surface 34b.

The multiple protrusions 341 each extend linearly on the bottom surface 34a, in the direction in which the externally recessed portion 34 extends, and are arranged in the cross direction. The top of each protrusion 341 is located below the element upper surface 3b.

The multiple projections 342 are disposed on the side surface 34b and arranged in the vertical direction. In the present embodiment, each projection 342 extends linearly in the direction in which the externally recessed portion 34 extends. The multiple projections 342 are disposed throughout the entire side surface 34b of the externally recessed portion in the vertical direction. More specifically, the side surface 34b of the externally recessed portion is an uneven surface, with the multiple projections 342 and recesses between the multiple projections 342 alternating in the vertical direction.

In the pressure sensor 1A according to the second embodiment, the externally recessed portion 34 recessed downward to a lesser depth than the groove portion 32 is disposed to be continuous with the outer side surface 32b of the groove portion in the cross direction. As compared to the structure not including the externally recessed portion 34, this structure allows the film 103 having flexibility to enter the groove portion 32 to a deeper position while the covering resin 4 is formed. This structure improves adhesion between the film 103 and the detecting element 3. This structure can thus reduce the likelihood of a high-fluidity substance accessing the interface S1 between the film 103 and the detecting element 3 or reduce the likelihood of a high-fluidity substance moving inward along the interface S1.

In the pressure sensor 1A according to the second embodiment, the externally recessed portion 34 includes the multiple projections 342 disposed on the side surface 34b and arranged in the vertical direction. In this structure, in the process of forming the covering resin 4, the film 103 enters the recesses between the projections 342. As compared to a structure not including the projections 342, this structure improves adhesion between the film 103 and the side surface 34b of the externally recessed portion.

Each projection 342 reduces upward movement of the film 103 located in the recesses immediately below the projection 342. Thus, even when a force of pulling the film 103 upward is unintentionally exerted on the film 103, adhesion between the film 103 and the side surface 34b of the externally recessed portion can be more reliably maintained.

In addition, the presence of the projections 342 increases the length of the interface S1 between the film 103 and the detecting element 3 in the cross section of the groove portion 32, the internally recessed portion 33, and the externally recessed portion 34. This structure less easily allows uncured resin to reach the detector 31. This structure can thus further reduce the likelihood of uncured resin reaching the detector 31.

### Third Embodiment

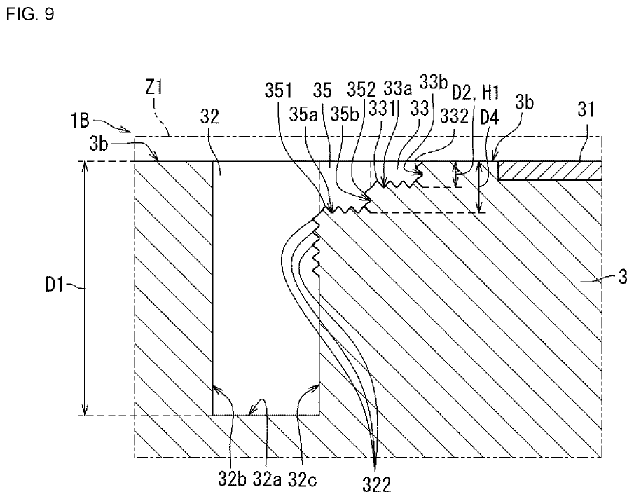

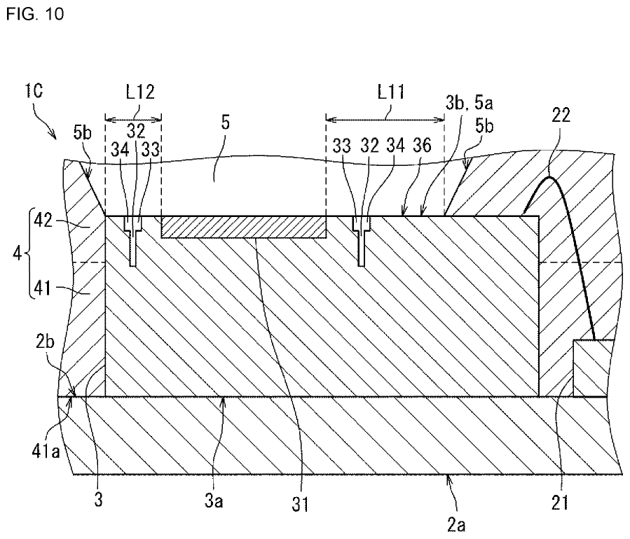

With reference to FIG. 9, a pressure sensor according to a third embodiment of the present disclosure is described. FIG. 9 is an enlarged cross-sectional view of a pressure sensor according to a third embodiment of the present disclosure, corresponding to the view in FIG. 4.

A pressure sensor 1B according to the third embodiment differs from the pressure sensor 1 according to the first embodiment in that the detecting element 3 includes a second internally recessed portion 35. In the description of the third embodiment below, the same components as those in the pressure sensor 1 may be denoted with the same reference signs and are not described.

As illustrated in FIG. 9, in the pressure sensor 1B, the detecting element 3 includes a first internally recessed portion 33 and a second internally recessed portion 35. The first internally recessed portion 33 corresponds to the internally recessed portion 33 of the pressure sensor 1 according to the first embodiment.

The second internally recessed portion 35 is located between the groove portion 32 and the first internally recessed portion 33 in the cross direction to be continuous with both the groove portion 32 and the first internally recessed portion 33, and recessed downward from the element upper surface 3b. FIG. 9 illustrates boundaries between the groove portion 32 and the first internally recessed portion 33 and between the groove portion 32 and the second internally recessed portion 35 with broken lines.

In the present embodiment, the groove portion 32, the first internally recessed portion 33, and the second internally recessed portion 35 are rotationally symmetric about the virtual center axis VA1 (refer to FIG. 3). Thus, the groove portion 32, the first internally recessed portion 33, and the second internally recessed portion 35 have the same cross section as the cross section illustrated in FIG. 9 throughout the entire periphery. The direction in which the second internally recessed portion 35 extends matches the direction in which each of the groove portion 32 and the first internally recessed portion 33 extends.

As illustrated in FIG. 9, a depth D4 of the second internally recessed portion 35 from the element upper surface 3b is smaller than the depth D1 of the groove portion 32, and greater than the depth D2 of the first internally recessed portion 33. Thus, the groove portion 32, the second internally recessed portion 35, and the first internally recessed portion 33 are formed in a stepped shape, rising inward in the cross direction. In the present embodiment, the depth D4 of the second internally recessed portion 35 is 8 μm.

The second internally recessed portion 35 has a bottom surface 35a intersecting with the vertical direction, and a side surface 35b that extends in the vertical direction, and connects the bottom surface 35a and the bottom surface 33a of the first internally recessed portion. The bottom surface 35a connects the side surface 35b and the inner side surface 32c of the groove portion in the cross direction.

The bottom surface 33a of the first internally recessed portion connects the side surface 33b of the first internally recessed portion and the inner side surface 32c of the groove portion with the bottom surface 35a and the side surface 35b of the second internally recessed portion interposed therebetween.

As in the first internally recessed portion 33, the second internally recessed portion 35 includes multiple protrusions 351 disposed on the bottom surface 35a, and multiple projections 352 disposed on the side surface 35b. The multiple protrusions 351 correspond to the multiple protrusions 331 of the first internally recessed portion 33. The multiple projections 352 correspond to the multiple projections 332 of the first internally recessed portion 33.

In the pressure sensor 1B according to the third embodiment, the second internally recessed portion 35 is disposed between the groove portion 32 and the first internally recessed portion 33 in the cross direction. In this structure, while the covering resin 4 is formed, a high-fluidity substance that moves inward while trickling along the film 103 comes into contact with the side surface 35b of the second internally recessed portion in addition to the inner side surface 32c of the groove portion and the side surface 33b of the first internally recessed portion. This structure can thus further reduce inward movement of a high-fluidity substance.

As compared to a structure not including the second internally recessed portion 35, this structure allows the film 103 having flexibility to enter the groove portion 32 to a deeper position. This structure further improves adhesion between the film 103 and the detecting element 3. This structure can thus further reduce the likelihood of a high-fluidity substance accessing the interface S1 between the film 103 and the detecting element 3 or reduce the likelihood of a high-fluidity substance moving inward along the interface S1.

This structure can thus further reduce the likelihood of uncured resin reaching the detector 31.

### Fourth Embodiment

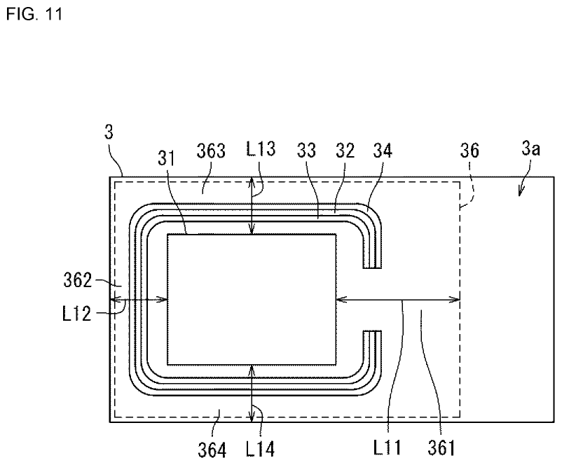

With reference to FIG. 10 and FIG. 11, a pressure sensor according to a fourth embodiment of the present disclosure is described. FIG. 10 is a cross-sectional view of the pressure sensor according to the fourth embodiment of the present disclosure. FIG. 10 illustrates the detector 31 and the surrounding portion in an enlarged manner. FIG. 11 is a plan view of an element upper surface of the pressure sensor according to the fourth embodiment of the present disclosure.

A pressure sensor 1C according to a fourth embodiment differs from the pressure sensor 1B according to the third embodiment in that the groove portion 32, the internally recessed portion 33, and the externally recessed portion 34 have gaps. In the description of the fourth embodiment below, the same components as those in the pressure sensor 1B may be denoted with the same reference signs and not described.

As illustrated in FIG. 10, the element upper surface 3b of the detecting element 3 has an exposure area 36 exposed through the covering resin 4 at the covering recess 5. The detector 31, and the groove portion 32, the internally recessed portion 33, and the externally recessed portion 34 that surround the detector 31 in a plan view are disposed in the exposure area 36.

As illustrated in FIG. 11, the detector 31 and the exposure area 36 are rectangles, in a plan view, having sides extending in the lateral direction and the depth direction intersecting with each other. The groove portion 32, the internally recessed portion 33, and the externally recessed portion 34 are substantially rectangular in a plan view, having sides extending in the lateral direction and the depth direction.

The exposure area 36 includes, in the lateral direction, a right area 361 or an area on the right of the detector 31, and a left area 362 or an area on the left of the detector 31 in the lateral direction. The exposure area 36 also includes, in the depth direction, a rear area 363 or an area at the rear of the detector 31, and a front area 364 or an area in front of the detector 31. In the description given below, the right area 361, the left area 362, the rear area 363, and the front area 364 may be collectively referred to as four areas 361 to 364.

For example, the right area 361 is an area on the right of the right side of the detector 31 and virtual extension lines of the right side in a plan view. The left area 362 is an area on the left of the left side of the detector 31 and virtual extension lines of the left side in a plan view. The rear area 363 is an area at the rear of the rear side of the detector 31 and virtual extension lines of the rear side in a plan view. The front area 364 is an area in front of the front side of the detector 31 and virtual extension lines of the front side in a plan view.

FIG. 11 illustrates distances L11 to L14 in the four areas 361 to 364 between the detector 31 and the outer edge of the exposure area 36. The distance L11 is a distance in the right area 361 between the detector 31 and the outer edge of the exposure area 36. The distance L12 is a distance in the left area 362 between the detector 31 and the outer edge of the exposure area 36. The distance L13 is a distance in the rear area 363 between the detector 31 and the outer edge of the exposure area 36. The distance L14 is a distance in the front area 364 between the detector 31 and the outer edge of the exposure area 36. For example, each of the distances L11 to L14 is a shortest distance in the corresponding one of the four areas 361 to 364.

In the present embodiment, the distance L11 is the longest in the four distances L11 to L14.

The groove portion 32, the internally recessed portion 33, and the externally recessed portion 34 are disposed to surround the detector 31 in a plan view. The groove portion 32, the internally recessed portion 33, and the externally recessed portion 34 are interrupted in one of the four areas 361 to 364 having the longest one of the four distances L11 to L14. In the present embodiment, the groove portion 32, the internally recessed portion 33, and the externally recessed portion 34 are interrupted in the right area 361 having the distance L11.

Herein and in the scope of claims, “surrounding the detector” refers to not only that the loop-shaped groove portion 32, the loop-shaped internally recessed portion 33, or the loop-shaped externally recessed portion 34 surrounds the detector 31, but also that one or more of the interrupted groove portion 32, the interrupted internally recessed portion 33, and the interrupted externally recessed portion 34 surround the detector 31 as a whole.

In the procedure of manufacturing the pressure sensor 1C, resin that has entered the interface S1 (refer to FIG. 7) is unlikely to reach the detector 31 as the distance from the outer edge of the exposure area 36 to the detector 31 is longer. In the present embodiment, as compared to the other three areas 362 to 364, the resin is unlikely to reach the detector 31 in the right area 361 having the longest distance L11. In the present embodiment, the groove portion 32, the internally recessed portion 33, and the externally recessed portion 34 are interrupted in the right area 361 that reduces the likelihood of resin reaching the detector 31. Even a structure in which the groove portion 32, the internally recessed portion 33, and the externally recessed portion 34 are interrupted in a plan view can reduce the likelihood of resin that has entered the interface S1 reaching the detector 31.

The present disclosure is not limited to the above embodiments, and may be embodied in various other forms. For example, in the above description, the covering resin 4 includes the body 41 with a rectangular prism shape and the covering protrusion 42 with a truncated cone shape, but the present disclosure is not limited to this example. The covering resin 4 may have any shape that allows the detector 31, the groove portion 32, and the internally recessed portion 33 to be exposed through the covering recess 5. For example, the covering resin 4 may be a rectangular prism having the covering recess 5 recessed downward from the upper surface.

Each of the pressure sensors 1 and 1A to 1C described above includes the corresponding protrusions 331, 341, or 351, but the present disclosure is not limited to this example. Each of the pressure sensors 1 and 1A to 1C may include no protrusions 331, 341, or 351.

In the above description, the projections 322 are disposed on the inner side surface 32c of the groove portion, but the present disclosure is not limited to this example. For example, the groove portion 32 may include protrusions protruding from the outer side surface 32b, similar to the projections 322. Alternatively, the groove portion 32 may include no projections 322.

In the third embodiment, one internally recessed portion (second internally recessed portion 35) is disposed between the groove portion 32 and the first internally recessed portion 33, but the present disclosure is not limited to this example. For example, multiple internally recessed portions continuous with the groove portion 32 and the first internally recessed portion 33 may be disposed between the groove portion 32 and the first internally recessed portion 33 in the cross direction. In this case, the bottom surface of each of the multiple internally recessed portions may be located above the bottom surface 32a of the groove portion, and the bottom surfaces of the internally recessed portions may be progressively positioned higher as they are located further inward. In other words, the first internally recessed portion 33 and the multiple internally recessed portions located on the outer side of the first internally recessed portion 33 may be formed in a stepped shape, rising inward in a cross section of the groove portion 32. This stepped shape can increase the barriers to a high-fluidity substance that moves inward along the interface S1 between the film 103 and the detecting element 3, and thus can further reduce the likelihood of uncured resin reaching the detector.

Multiple externally recessed portions may be disposed outside the groove portion 32. In this case, the bottom surface of each of the multiple externally recessed portions may be located above the bottom surface 32a of the groove portion, and the bottom surfaces of the externally recessed portions may be progressively positioned higher as they are located further outward. In other words, the multiple externally recessed portions may be formed in a stepped shape, rising outward in a cross section of the groove portion 32. This stepped shape allows the film 103 having flexibility to enter the groove portion 32 to a deeper position. This structure improves adhesion between the film 103 and the detecting element 3.

In the fourth embodiment, the groove portion 32, the internally recessed portion 33, and the externally recessed portion 34 are interrupted in one of the four areas 361 to 364 having the longest one of the four distances L11 to L14, but the present disclosure is not limited to this example. For example, instead of the area having the longest distance, the groove portion 32, the internally recessed portion 33, and the externally recessed portion 34 may be interrupted in any area having any of the distances L11 to L14 that reduces the likelihood of resin, that has entered the interface S1, reaching the detector 31.

By combining any two or more of the various embodiments and modifications as appropriate, the effects of the embodiments or the modification may be achieved. Any two or more of the embodiments may be combined, any two or more of the examples may be combined, any two or more of the embodiments and the examples may be combined, or features in different two or more of the embodiments and examples may be combined.

The present disclosure has been fully described with reference to the preferred embodiments illustrated in the accompanying drawings. However, various modifications and corrections will be apparent to those skilled in the art. Such modifications and corrections should be understood to be included within the scope of the present disclosure as long as they do not depart from the scope defined by the appended claims.

The present disclosure can reduce the likelihood of uncured resin reaching a detector, and is thus useful to various pressure sensors.

### REFERENCE SIGNS LIST

1, 1A to 1C pressure sensor
2 substrate
2b upper surface
3 detecting element
3b element upper surface
31 detector
32 groove portion
32b outer side surface
32c inner side surface
33 internally recessed portion (first internally recessed portion)
33a bottom surface
33b side surface
331 protrusion
332 projection
34 externally recessed portion
34a bottom surface
34b side surface
342 projection
4 covering resin
5 covering recess

1. A pressure sensor comprising:
a substrate having a first surface and a second surface opposing each other in a thickness direction thereof;
a detecting element adjacent the first surface of the substrate and configured to detect a pressure; and
a covering resin adjacent the first surface of the substrate and covering a part of the detecting element,
wherein the covering resin defines a covering recess that is recessed toward the first surface of the substrate such that at least a part of an element surface of the detecting element is exposed therethrough,
wherein the detecting element includes:
a detector disposed at a portion of the element surface exposed through the covering recess,
a groove portion that is recessed downward from the element surface and that surrounds the detector in a plan view of the pressure sensor, and
an internally recessed portion between the groove portion and the detector in the plan view and continuous with the groove portion, the internally recessed portion being recessed toward the first surface of the substrate to a lesser depth than the groove portion,
wherein the groove portion has a first side surface and a second side surface, the second side surface being closer to the detector than the first side surface in the plan view, and the second side surface faces the first side surface, and
wherein the internally recessed portion has a third side surface extending toward the first surface of the substrate from the element surface, and a bottom surface extending toward the first side surface from an edge portion of the third side surface of the internally recessed portion.

2. The pressure sensor according to claim 1, wherein a width of the internally recessed portion is smaller than a width of the groove portion.

3. The pressure sensor according to claim 1, wherein a height of the internally recessed portion is smaller than a width of the internally recessed portion.

4. The pressure sensor according to claim 1, wherein a width of the internally recessed portion is smaller than a distance between the third side surface of the internally recessed portion and the detector along the element surface.

5. The pressure sensor according to claim 1, wherein the internally recessed portion includes a plurality of projections extending from the third side surface of the internally recessed portion.

6. The pressure sensor according to claim 1, wherein a height of the third side surface of the internally recessed portion is smaller than a length of the bottom surface of the internally recessed portion between the edge portion of the third side surface of the internally recessed portion and the second side surface of the groove portion.

7. The pressure sensor according to claim 1, wherein a length of the bottom surface of the internally recessed portion between the edge portion of the third side surface of the internally recessed portion and the second side surface of the groove portion is smaller than a distance between the detector and the third side surface of the internally recessed portion at the element surface.

8. The pressure sensor according to claim 1, wherein the detecting element further includes an externally recessed portion that is continuous with the first side surface of the groove portion in the plan view, and that is recessed toward the first surface of the substrate to a lesser depth than the groove portion.

9. The pressure sensor according to claim 8, wherein the externally recessed portion has
a fourth side surface extending toward the first surface of the substrate from the element surface, and
a bottom surface extending from an edge portion of the fourth side surface of the externally recessed portion toward the first side surface of the groove portion.

10. The pressure sensor according to claim 9, wherein the externally recessed portion has a plurality of projections on the fourth side surface of the externally recessed portion.

11. The pressure sensor according to claim 1, wherein the internally recessed portion includes a plurality of protrusions on the bottom surface of the internally recessed portion, and arranged, in the plan view, in a direction from the second side surface of the groove portion to the third side surface of the internally recessed portion.

12. The pressure sensor according to claim 11, wherein a height of each of the plurality of protrusions is smaller than a depth of the internally recessed portion.

13. The pressure sensor according to claim 1, wherein the groove portion includes multiple projections on the second side surface.

14. The pressure sensor according to claim 13, wherein the multiple projections are on a part of the second side surface of the groove portion.

15. The pressure sensor according to claim 1, wherein the internally recessed portion includes:
a plurality of projections extending from the third side surface of the internally recessed portion, and
a plurality of protrusions on the bottom surface of the internally recessed portion, and arranged, in the plan view, in a direction from the second side surface of the groove portion to the third side surface of the internally recessed portion.

16. The pressure sensor according to claim 10, wherein the internally recessed portion includes:
a plurality of projections extending from the third side surface of the internally recessed portion, and
a plurality of protrusions on the bottom surface of the internally recessed portion, and arranged, in the plan view, in a direction from the second side surface of the groove portion to the third side surface of the internally recessed portion.

17. The pressure sensor according to claim 1, wherein the internally recessed portion is a first internally recessed portion, and the detecting element further includes a second internally recessed portion between the groove portion and the first internally recessed portion, the second internally recessed portion being continuous with both the groove portion and the first internally recessed portion, and recessed toward the first surface of the substrate to a lesser depth than the groove portion.

18. The pressure sensor according to claim 17, wherein a depth of the second internally recessed portion from the element surface is smaller than a depth of the groove portion, and greater than a depth of the first internally recessed portion.

19. The pressure sensor according to claim 18, wherein the second internally recessed portion has
a fourth side surface extending toward the first surface of the substrate from the bottom surface of the first internally recessed portion, and
a bottom surface extending from an edge portion of the fourth side surface of the second internally recessed portion toward the first side surface of the groove portion.

20. The pressure sensor according to claim 19, wherein the second internally recessed portion has
a plurality of projections on the fourth side surface, and
a plurality of protrusions on the bottom surface, and arranged, in the plan view, in a direction from the second side surface of the groove portion to the fourth side surface of the second internally recessed portion.
